(19) United States
(12) Patent Application Publication
(10) Pub. No.: US 2018/0238939 A1
(43) Pub. Date: Aug. 23, 2018

(54) EXPECTED SENSOR MEASUREMENT RECEIPT INTERVAL ESTIMATION

(71) Applicant: Hewlett Packard Enterprise Development LP, Houston, TX (US)

(72) Inventors: Ron Maurer, Haifa (IL); Shahar Tal, Yehud (IL)

(21) Appl. No.: 15/438,259

(22) Filed: Feb. 21, 2017

(51) Int. Cl. G01R 19/25; G01R 35/00; G04F 10/00

(52) U.S. Cl. CPC G01R 19/25; G04F 10/00; G01R 35/00

(57) ABSTRACT

A current measurement receipt interval is computed as a difference between a current receipt time of a current measurement from a sensor and a previous receipt time of a previous measurement from the sensor. An expected measurement receipt interval is estimated, based on a lowest mode of measurement receipt intervals including the computed current measurement receipt interval.

### BACKGROUND

Modern electronic systems can include distributed systems in which device sensors measuring data are located remotely to the processing devices that collect and analyze the data, and that can perform remediation actions depending on the data collected and whether the sensors have reported their measured data. Examples of such distributed systems including information technology (IT) systems having multitudes of server computing devices located across data centers, industrial computer-controlled devices including robotic devices, and “Internet of Things” devices that may have limited processing capability beyond the ability to measure and report data. A given processing device may be responsible for collecting data from hundreds, thousands, or even more of such device sensors.

### BRIEF DESCRIPTION OF THE DRAWINGS

FIG. 1 is an illustrative diagram of an example expected sensor measurement receipt interval.

FIG. 2 is a flowchart of an example method for estimating an expected sensor measurement receipt interval.

FIG. 3 is a graph of an example histogram of mode occurrence counts of sensor measurement receipt intervals.

FIG. 4 is a flowchart of an example method for estimating an expected sensor measurement receipt interval, consistent with but more detailed than the method of FIG. 2.

FIG. 5 is a flowchart of an example method for using an estimated expected measurement receipt interval as a trigger on which basis to perform a remedial action.

FIG. 6 is a diagram of an example system.

### DETAILED DESCRIPTION

As noted in the background section, within a distributed system a processing device may be responsible for collecting and analyzing sensor data of a large number of device sensors. Such sensor data collection generally occurs in a “push” manner as opposed to a “pull” manner due to the large number of device sensors involved. That is, rather than the processing device periodically polling each device sensor to “pull” measured sensor data from the device sensors, each device sensor is configured to periodically “push” its measured sensor data to the processing device automatically.

Although the pushing of measured data from a sensor to a processing device can theoretically occur at a constant, regular frequency, in actuality deviations within the reporting frequency result. Normal communication delays over the network can impart variability in the sensor data collection interval. Periodic data drops can occur, either due to communication issues, or because the measurement and reporting of the data at the sensor device is skipped for a given interval due to other, higher priority processing that the device is performing. A sensor device may go offline for a period of time before coming back online, causing a gap in the collection of measured data from the device.

Many types of sensor data analysis, such as those on which basis device abnormality detection and corresponding reactive remedial actions are performed, may at least implicitly have to know the expected sensor measurement receipt interval of each sensor from which data is being collected. The processing device may be manually configured with this information for each sensor, and then reconfigured if and when the frequency at which a sensor reports data changes. However, when a processing device collects data from any more other than a relatively small number of sensors, such manual configuration quickly becomes untenable and infeasible.

Techniques described herein, by comparison, estimate an expected sensor measurement receipt interval without any a priori knowledge regarding the frequency at which a sensor is reporting data. The expected sensor measurement receipt interval is when a processing device expects to receive the next measurement from a sensor after the currently received measurement from the sensor. The expected sensor measurement receipt interval is dynamically updated as measurements are received from the sensor, and takes into account normal delays in the communication of measurements from the sensor to the processing device, as well as periodic data drops and data gaps in the sensor's reporting of its measured data.

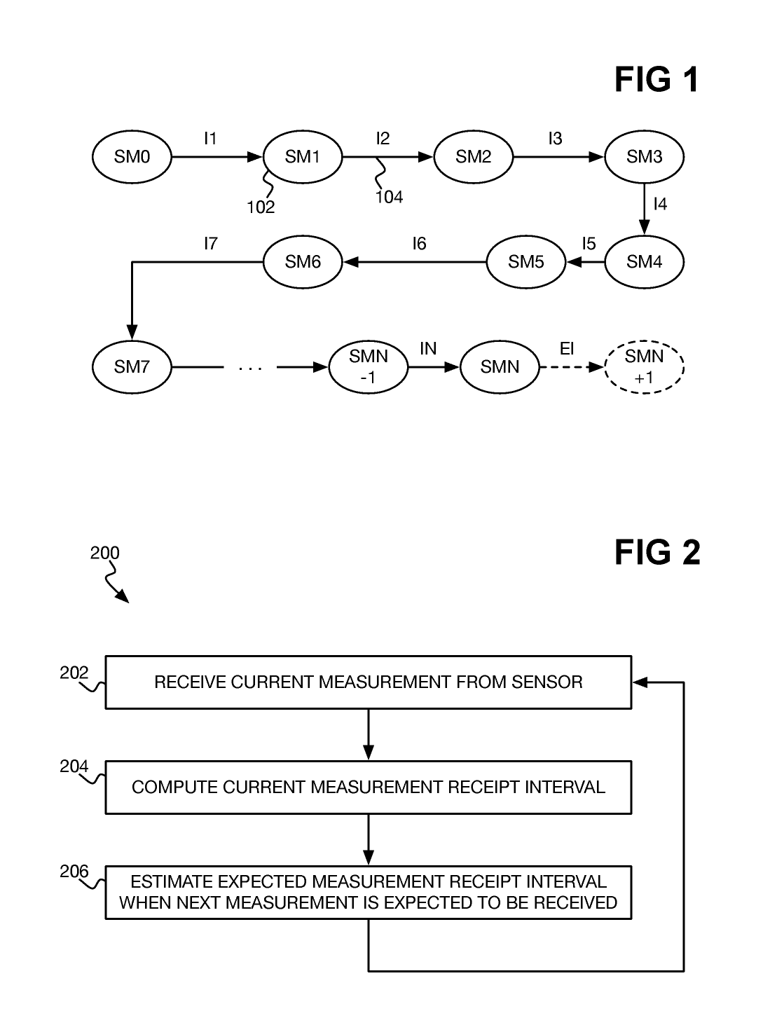

FIG. 1 graphically illustrates an example of an expected sensor measurement receipt interval. Received sensor measurements are depicted as ovals 102 in FIG. 1, whereas sensor measurement receipt intervals are depicted as arrow-terminated lines 104. A processing device thus receives a sensor measurement SM0 from a sensor, and after a time interval 11, receives a sensor measurement SM1 from the sensor, and so on. As such, the processing device receives sensor measurements SM0, SM1, SM2, SM3, SM4, SM5, SM6, SM7, . . . , SMN-1, SMN in the example of FIG. 1, in which consecutive sensor measurements are received at time intervals I1, I2, I3, I4, I5, I6, I7, . . . , IN.

The sensor may be programmed with a set frequency at which the sensor reports measurements to the processing device. However, in the example of FIG. 1, in actuality the processing device receives the sensor reports at receipt intervals that can vary. As described above, such variation can result from normal communication delays between the sensor and the processing device, as well as periodic data drops and data gaps. In this respect, it is noted that the intervals at which the sensor reports, or sends, measurements to the processing device can differ from the intervals at which the processing device receives the measurements from the sensor.

As the sensor measurements are received from the sensor, the processing device estimates when the next sensor measurement is expected to be received from the sensor. In the example of FIG. 1, for instance, once sensor measurement SM1 received, the processing device estimates when the next sensor measurement SM2 is expected to be received. Stated another way, the processing device estimates the expected sensor measurement receipt interval I2. This process continues with each receipt sensor measurement. In the example of FIG. 1, the last received sensor measurement that has been received is the sensor measurement SMN. The processing device thus estimates the expected sensor measurement receipt interval EI when the next sensor measurement SMN+1 is expected to arrive.

FIG. 2 shows an example method 200 of the general process by which a processing device estimates when a next sensor measurement is expected to be received from a sensor. The method 200 can be implemented as computer-executable code stored on a non-transitory computer-readable data storage medium of the processing device, and execute by a processor of the processing device. The processing device is communicatively connected to the sensor. For instance, the sensor and the processing device may be communicatively connected to one another over a network.

The processing device receives a current measurement from the sensor (202), and correspondingly computes a current measurement receipt interval (204). The current measurement receipt interval is the difference between the time at which the current measurement was received from the sensor and the time at which the immediately prior measurement was received from the sensor. In the example of FIG. 1, for instance, if the current measurement is the sensor measurement SM3 and was received at a time t3, then the immediately prior measurement is the sensor measurement SM2. If the sensor measurement SM2 was received at a time t2, then the current measurement receipt interval 13 is computed as t3-t2.

The processing device estimates the expected measurement receipt interval as to when the next measurement is expected to be received (206). In the example of FIG. 1, for instance, if the current measurement is the sensor measurement SM3, then the expected measurement receipt interval is 14, which is when the sensor measurement SM4 is expected to be received. The processing device estimates the expected measurement receipt interval based on the measurement receipt intervals that have been computed thus far, including the just-computed current measurement receipt interval. For instance, in FIG. 1, if the current measurement is the sensor measurement SM3, then the expected measurement receipt interval I4 is estimated based on the measurement receipt intervals I1, I2, and I3 that have been computed.

The expected measurement receipt interval is generally estimated as the lowest mode of the measurement receipt intervals that have been computed, such as the lowest logarithmic base two mode of these intervals, which can also be referred to as the lowest logarithmic base two significant mode. The expected measurement receipt interval can be estimated based on the cumulative weighted inverse mean of this lowest mode. Such a basis for estimation is different than, for instance, the cumulative median of the measurement receipt intervals that have been computed, or the most frequent lowest mode.

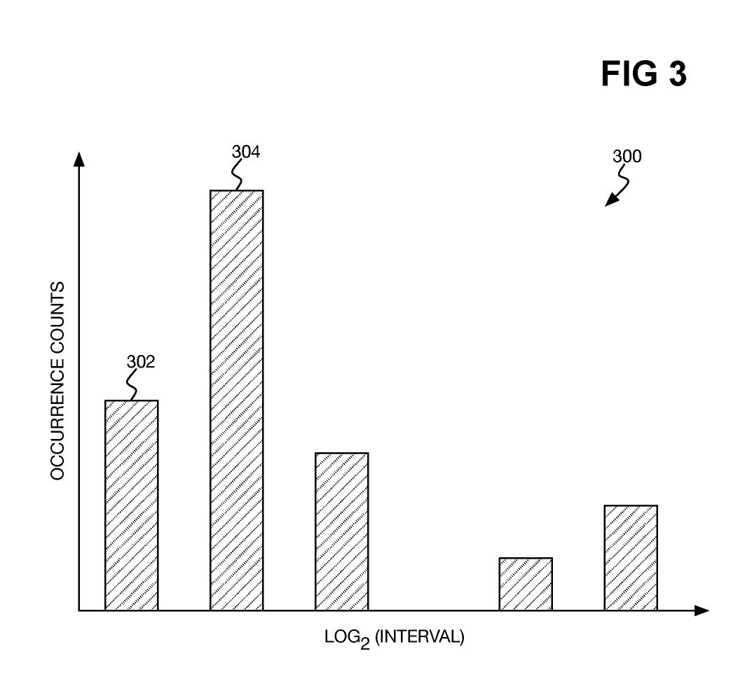

FIG. 3 shows an example histogram 300 depicting selection of the lowest mode of the measurement receipt intervals as the expected measurement receipt interval. The histogram 300 groups the base two logarithms of the measurement receipt intervals into modes, five of which are depicted in the example of FIG. 3. The histogram 300 indicates the number of measurement receipt intervals that have values in each group. The lowest mode 302 is not the mode having the greatest number of measurement receipt intervals. Rather, the mode 304 has the greatest number of measurement receipt intervals.

Nevertheless, the lowest mode 302 corresponds to the expected measurement receipt interval at which the next sensor measurement is expected to be received from the sensor. It is noted that the cumulative median of the measurement receipt intervals would be greater than (and thus different than) measurement receipt intervals grouped within the lowest mode 302. Similarly, the most frequent mode is the mode 304, which corresponds to measurement receipt intervals that are greater than (and thus different than) measurement receipt intervals grouped within the mode 302.

Mathematically, for sensor measurements indexed by k≥1, measurement k is received at time tₖ, after a measurement receipt interval Δtₖ=tₖ−tₖ₋₁. Stated another way, when a current measurement k is received, at time tₖ, the current measurement receipt interval Δtₖ is equal to the time tₖ at which the current measurement k was received minus the time tₖ₋₁ at which the previous measurement k-1 was received. The lowest mode of the k sensor measurements received thus far can be represented as ΔT₀[k], such that the next sensor measurement k+1 is expected to be received at tₖ₊₁=tₖ+Δt₀[k]. In other words, the expected measurement receipt interval is estimated as ΔT₀[k].

The expected measurement receipt interval can be based on the cumulative weighted inverse mean of the lowest mode of the measurement receipt intervals received thus far, (ΔT₀[k])⁻². In one implementation, for instance,

$${( Δ {T}_{0} [ k ] )}^{- 2} = \frac{{Σ}_{i = 1}^{k} Δ {t}_{i}^{- 4}}{{Σ}_{i = 1}^{k} Δ {t}_{i}^{- 2}} . \qquad ( 1 )$$

In equation (1), the cumulative weighted inverse mean of the lowest mode is equal to a numerator divided by a denominator. The numerator is equal to, and more generally based on, the sum of the inverse fourth powers of the measurement receipt intervals. The denominator is equal to, and more generally based on, the sum of the inverse squares of the measurement receipt intervals.

Equation (1) describes a weighted mean of the values Δtᵢ⁻⁴ through i=k. The weight for participating in the mean is thus Δtᵢ⁻². This weighting emphasizes values of Δtᵢ⁻⁴ that are relatively larger than the others, so that the mean is biased towards the smallest values of Δtᵢ. The result is an approximation of the fundamental measurement interval to within one percent, even if the lowest mode contains as few as about twenty percent of the measurement intervals.

Stated another way, the cumulative weighted inverse mean of the lowest mode can be considered cumulative in that it accumulates from i=1 through i=k. The cumulative weighted inverse mean can be considered weighted in that it is weighted by Δtᵢ⁻². The cumulative weighted inverse mean can be considered inverse in that Δtᵢ⁻⁴ is a (fourth power) inverse of Δtᵢ. The cumulative weighted inverse mean can be considered a mean in that the numerator of equation (1) describes a sum that is effectively divided by a weighted count, which is described in the denominator.

The estimation of equation (1) is not influenced by occasional drops, because even missing one measurement has about one-sixteenth of the influence of the other measurements within the fundamental interval. A relatively long drop in measurement receipts, such as by a factor of fifty of the fundamental interval, is in effect excluded from consideration. The fundamental interval is the interval at which the sensor itself has been configured to report measurements to the processing device, which if there were no transmission delays and no dropouts or measurement gaps, means that the processing device would receive sensor measurements at multiples of this interval.

Equation (1) can be rewritten to express the ability to update the estimated expected measurement receipt interval as new measurement receipt intervals are computed (i.e., as new measurements are received from the sensor):

$${( Δ {T}_{0} [ k ] )}^{- 2} = \frac{{Σ}_{i = 1}^{k} Δ {t}_{i}^{- 4}}{{Σ}_{i = 1}^{k} Δ {t}_{i}^{- 2}} = \frac{{S}_{- 4} [ k ]}{{S}_{- 2} [ k ]} = \frac{{S}_{- 4} [ k - 1 ] + Δ {t}_{k}^{- 4}}{{S}_{- 2} [ k - 1 ] + Δ {t}_{k}^{- 2}} . \qquad ( 2 )$$

This means that for a given sensor, just three state variables have to be maintained to update the estimated expected measurement receipt interval as sensor measurements are received: the current cumulative numerator, S₋₄[k], the current cumulative denominator, S₋₂[k], and the time tₖ at which the current measurement was received, which is used to compute the measurement receipt interval when the next measurement is received. Therefore, the expected measurement time interval estimation of equation (2) is memory efficient, which can be desired when there are thousands or even more sensors for which the processing device is responsible. Likewise, the expected measurement time interval estimation of equation (2) is computationally efficient, because when a sensor measurement is received, the nominator and denominator of equation (1) do not have to be recomputed by reevaluating their respective constituent sums, but rather just to be each updated with the addition of one addend or summand, per equation (2).

In one implementation, when a new measurement k is received at time tₖ, the existing cumulative numerator and the cumulative denominator (i.e., for time tₖ₋₁) are each multiplied by a decay factor before being updated by their respective inverse fourth power and inverse square of the current measurement receipt interval Δtₖ. That is,

s_{-q}[k]=w_{decay}·s_{-q}[k−1]+Δtₖ^{-q}. (3).

In equation (3), q is equal to four to specify the numerator of equation (2), and is equal to two to specify the denominator of equation (2). The decay factor w_{decay} can be equal to 2^{-(1/Nh)}, where Nh specifies a half-life constant that can be preset to a value of thirty or another value. The “units” of the half-life constant are received sensor measurements, such that a half-life constant of thirty corresponds to thirty measurements received from the sensor. The decay factor weights a sample that occurred Nh samples previously by one-half (i.e., consistent with what “half-life” means).

Usage of a decay factor ensures that if the fundamental interval at which the sensor is to report measurements to the processing device changes abruptly, such a change is more quickly detected and reflected in the expected measurement receipt interval ΔT₀[k]. The decay factor particularly ensures that the expected that measurement receipt interval more quickly reflects a change in the fundamental interval when k is relatively large—that is, a large number of sensor measurements have been received prior to the fundamental interval changing. The decay factor achieves this by decaying the existing cumulative numerator and denominator of equation (2) each time a new sensor measurement is received.

In another implementation, when a new measurement is received at time tₖ, the numerator and the denominator of equation (2) are updated by the inverse fourth power and the inverse square, respectively, of the current measurement receipt interval Δtₖ as weighted by a proximity effect weight that is a function of the current measurement receipt interval itself. That is, instead of just updating the numerator and denominator by Δtₖ⁻⁴ and Δtₖ⁻², respectively, the numerator and denominator are instead updated by wₚᵣₒₓ(Δtₖ)·Δtₖ^{-q}, where q is equal to four for the numerator and is equal to two for the denominator. The proximity effect weight can increase the robustness of the expected measurement receipt interval ΔT₀[k] against very short measurement receipt intervals (i.e., double measurements being quickly received one after another) as well as very frequent drops of measurements. The proximity effect weight can have a value that increases with the closeness of the current measurement receipt interval Δtₖ to the expected measurement receipt interval that has been estimated thus far, ΔT₀[k−1].

The proximity effect weight can be specified as

$${w}_{prox} ( Δ {t}_{k} ) = {( 1 + a • \vert {log}_{2} ( \frac{Δ {{T}_{0} [ k - 1 ]}^{2}}{Δ {t}_{k}^{2}} ) \vert )}^{- 2} . \qquad ( 4 )$$

In equation (4), the selectivity parameter a can be set to specify the strength of the proximity effect as desired. For instance, if a is set to one, the proximity weight becomes one when the current measurement receipt interval is equal to the expected measurement receipt interval estimated thus far (i.e., Δtₖ=ΔT₀[k−1]). The proximity effect decreases as the ratio

$$\frac{Δ {t}_{k}}{Δ {T}_{0} [ k - 1 ]}$$

deviates from one either positively or negatively.

The proximity effect weight is particularly effective once the expected measurement receipt interval has reached a steady state, such as after about two times Nh measurements. Specifying the selectivity parameter a as a function ensures that the proximity effect weight is similarly effective prior to steady state, such as if when sensor measurements are first received, there are frequent double measurements and/or measurement drops. The selectivity parameter a can be specified so that it is zero at the receipt of the first measurement (i.e., k is equal to one), and then gradually increases towards one (i.e., a approaches one as k>>1). For instance, the selectivity parameter a can be specified as a saturation curve function,

$$a [ k ] = 1 - {2}^{- {( \frac{k - 1}{Nh} )}^{2}} . \qquad ( 5 )$$

The selectivity parameter thus in effect biases the proximity effect weight towards temporally later computations of the expected measurement receipt interval and away from temporally earlier computations of the expected measurement receipt interval.

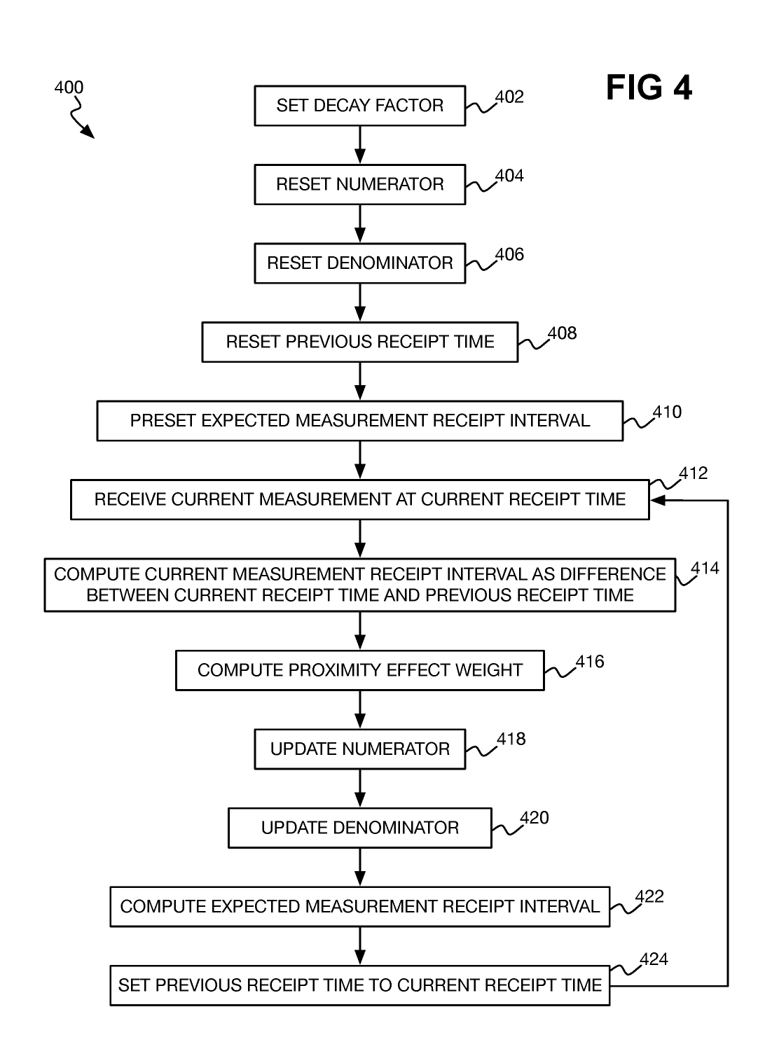

FIG. 4 shows an example method 400 for determining an expected measurement receipt interval as a processing device receives measurements from a sensor. The processing device can be a computing device communicatively connected to the sensor, such as over a network. The method 400 may be implemented as computer-executable code stored on a non-transitory computer-readable data storage medium and that a processor of such a computing device executes.

The processing device sets a decay factor W_{decay} (402), which is a constant. As noted above, the decay factor can be equal to 2^{-(1/Nh)}, where Nh is a constant specifies a half-life constant that can be preset to a value of thirty or another value. The processing device can maintain just three variables to determine the expected measurement receipt interval as sensor measurements are received, which are reset a priori: a cumulative numerator (404), S₋₄[k]; a cumulative denominator (406), S₋₂[k]; and the time at which a sensor measurement was previously received (408), which is referred to as a previous receipt time, tₖ₋₁. Each of these values is reset to a value of zero. The expected measurement receipt interval, ΔT₀[k=0], can also be preset to a relatively large value (410), such as 7,200, for initial computations of the proximity effect weight.

The processing device receives a current sensor from the sensor at a current receipt time tₖ (412). A current measurement receipt interval Δtₖ is computed as the difference between the current receipt time and the previous receipt time (414), tₖ−tₖ₋₁. A proximity effect weight wₚᵣₒₓ can be computed (416). The proximity effect weight is not a constant, but rather is a function of the current measurement receipt interval, such as in accordance with Equation (4) noted above. Computation of the proximity effect weight, like as in Equation (4), can depend on the prior expected measurement receipt interval ΔT₀[k−1]. The first time part 416 is performed, this is ΔT₀[k=0], as preset to a relatively large value. Subsequently, ΔT₀[k−1] is equal to the expected measurement receipt interval computed prior to receipt of the current measurement receipt interval.

The processing device updates the numerator S₋₄[k] (418) and the denominator (420) based on the current measurement receipt interval computed in part 414 and the proximity effect computed in part 416. For instance, the numerator and the denominator may be updated according to Equation (3) noted above, where q in this equation is set to four to update the numerator and is set to two to update the denominator. The processing device can then compute the expected measurement receipt interval (422), based on a ratio of the numerator to the denominator. For instance, the square root of this ratio can be computed as the expected measurement receipt interval, according to Equation (2) noted above.

The previous receipt time tₖ₋₁ is set to the current receipt time tₖ (424). As described above, the previous receipt time is one of three variables that the processing device stores in memory to permit computation of the expected measurement receipt interval as measurements are received from the sensor. The other two variables are the numerator and the denominator as updated in parts 418 and 420. The previous receipt time is maintained so that the current measurement receipt interval can be computed each time part 414 is performed. The expected measurement receipt interval, as the subject computation of the method 400, can also be maintained, particularly if a proximity effect weight is computed in part 416. The method 400 repeats at part 412 the next time the processing device receives a measurement from the sensor.

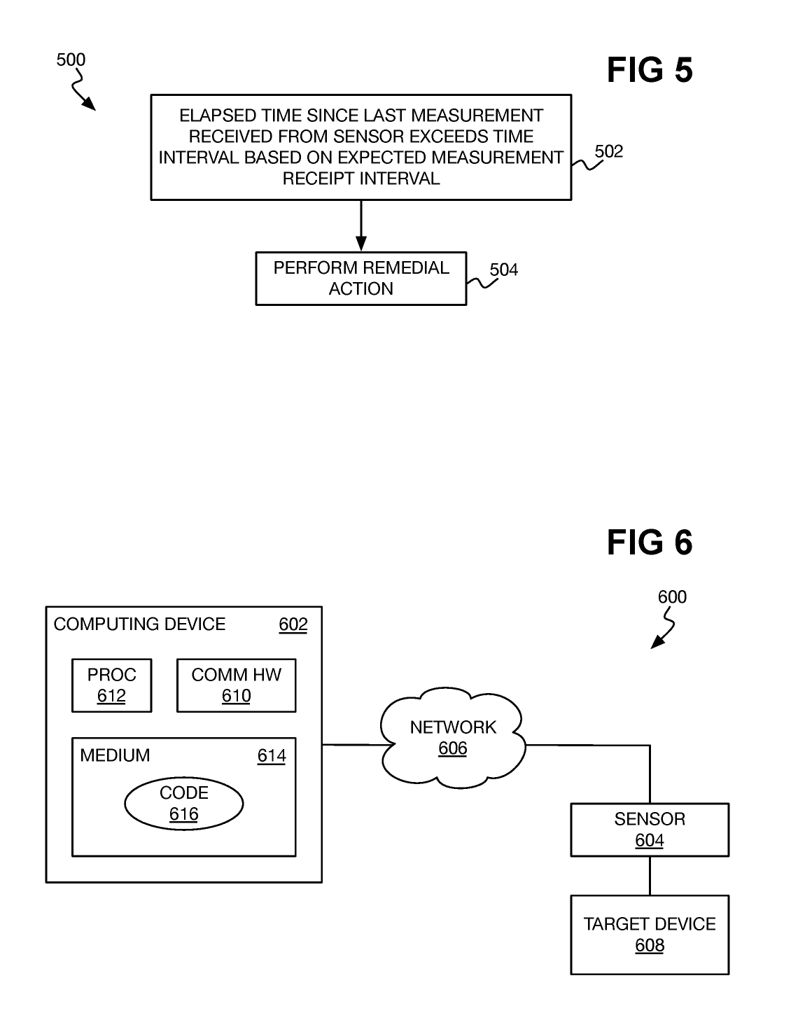

FIG. 5 shows an example method 500 as to how the computed expected measurement receipt interval can be used as a trigger on which basis to perform a remedial action. The processing device that computes the expected measurement receipt interval can also perform the method 500, or another computing device may perform the method 500. For instance, the processing device may output the measurements it receives from the sensor including the times at which the measurements are received, as well as the computed expected measurement receipt value, to a different computing device performing the method 500. The processing device may store the measurements, the times at which the measurements are received, and the computed expected measurement receipt value within a storage device that the computing device performing the method 500 can access, for instance, or the processing device may send this information to the computing device over a network.

The device performing the method 500 determines that the elapsed time since the last measurement was received from the sensor exceeds a time interval that is based on the computed expected measurement receipt interval (502). For instance, the time interval may simply be equal to the expected measurement receipt interval, or it may be equal to a multiple or a percentage greater than the expected measurement receipt interval. The time interval may be equal to the expected measurement receipt interval plus a threshold, as another example.

In response, the device performs a remedial action related to the sensor (504). The sensor may be part of a system like or including a target computing device. The remedial action can include a physical action performed on the system. For example, the target computing device may be rebooted, or powered off and the on. Thus, the remedial action is performed responsive to the elapsed time since the last measurement was received from the sensor exceeding a time interval based on the computed expected measurement receipt interval.

FIG. 6 shows an example system 600. The system 600 includes a computing device 602 and a sensor 604 that can be communicatively interconnected over a network 606. The sensor 604 measures a parameter of or pertaining to a target device 608, reporting measurements to the computing device 602. The parameter may be a physical value such as temperature, humidity, gaseous pressure, fluidic flow rate, and so on. The parameter may be a computing-related value, such as instantaneous processor utilization, data storage rate, and so on. The target device 608 may be a computing device or another type of device. The sensor 604 and the target device 608 may be part of a sub-system, which transmits the measurements read by the sensor 604 to the computing device 602.

The computing device 602 may a server or other type of computer. The computing device 602 includes communication hardware 610 by which the device 602 can communicatively connect to the network 602 to receive measurements from the sensor 604. For example, the communication hardware 610 may be a network adapter to connect the computing device 602 to a network 606 that can be or include a local-area network (LAN), a wide-area network (WAN), an intranet, an extranet, the Internet, a mobile telephony network, and so on.

The computing device 602 includes a processor 612 and a non-transitory computer-readable data storage medium 614 that stores computer-executable code 616. The processor 612 executes the code 616 from the medium 614 to perform the methods that have been described. Thus, the computing device 602 successively updates an expected measurement receipt interval as to when a next measurement is to be received from the sensor 604, as a lowest mode of the measurements, as the measurements are received from the sensor 604.

The techniques that have been described permit the computation of an expected measurement receipt interval with no a priori knowledge as to the interval at which a sensor has been configured to report measurements. The techniques that have been described can thus be easily employed in systems in which there are hundreds, thousands, or even more sensors that centrally report their measurements. Therefore, the techniques scale well with large numbers of sensors, and also because little data has to be stored for each sensor to permit the computation of the expected measurement receipt interval as measurements are received from the sensor in question.

We claim:

1. A non-transitory computer-readable data storage medium storing instructions executable by a processor to:
compute a current measurement receipt interval, as a difference between a current receipt time of a current measurement from a sensor and a previous receipt time of a previous measurement from the sensor; and
estimate an expected measurement receipt interval, based on a lowest mode of a plurality of measurement receipt intervals including the computed current measurement receipt interval.

2. The non-transitory computer-readable data storage medium of claim 1, wherein the instructions are executable by the processor to further:
use the expected measurement receipt interval as a trigger on which basis to perform a remedial action at a system including the sensor.

3. The non-transitory computer-readable data storage medium of claim 1, wherein the expected measurement receipt interval is estimated as being equal to a numerator based on a first sum of inverse fourth powers of the measurement receipt intervals divided by a denominator based on a second sum of inverse squares of the measurement receipt intervals.

4. The non-transitory computer-readable data storage medium of claim 3, wherein the numerator is equal to the first sum, and the denominator is equal to the second sum.

5. The non-transitory computer-readable data storage medium of claim 3, wherein the numerator is based on an inverse fourth power of the current measurement receipt interval plus a product of a decay factor and the first sum excluding the inverse fourth power of the current measurement receipt interval,
wherein the denominator is based on an inverse square of the current measurement receipt interval plus a product of the decay factor and the second sum excluding the inverse square of the current measurement receipt interval.

6. The non-transitory computer-readable data storage medium of claim 5, wherein the decay factor is equal to two to a power of a negative inverse of a half-life constant.

7. The non-transitory computer-readable data storage medium of claim 5, wherein the numerator is equal to the inverse fourth power of the current measurement receipt interval plus the product of the decay factor and the first sum excluding the inverse fourth power of the current measurement receipt interval,
wherein the denominator is equal to the inverse square of the current measurement receipt interval plus the product of the decay factor and the second sum excluding the inverse square of the current measurement receipt interval.

8. The non-transitory computer-readable data storage medium of claim 5, wherein the numerator is equal to product of a proximity effect weight of the current measurement receipt interval and the inverse fourth power of the current measurement receipt interval plus the product of the decay factor and the first sum excluding the inverse fourth power of the current measurement receipt interval,
wherein the denominator is equal to a product of the proximity effect weight of the current measurement receipt interval and the inverse square of the current measurement receipt interval plus the product of the decay factor and the second sum excluding the inverse square of the current measurement receipt interval.

9. The non-transitory computer-readable data storage medium of claim 8, wherein the proximity effect weight is based on a base two logarithm of a square of a prior lowest mode of the measurement receipt intervals excluding the current measurement receipt interval, divided by a square of the current measurement receipt interval.

10. The non-transitory computer-readable data storage medium of claim 9, wherein the proximity effect weight is based on a selectivity parameter multiplied by the base two logarithm of the square of the prior lowest mode of the measurement receipt intervals excluding the current measurement receipt interval, divided by the square of the current measurement receipt interval.

11. The non-transitory computer-readable data storage medium of claim 10, wherein the selectivity parameter starts at zero and approaches one with an increasing number of measurements received from the sensor.

12. A computer-implemented method performed by a computing device, the method comprising:
receiving a current measurement at a current receipt time from a sensor;
computing a current measurement receipt interval between the current receipt time and a previous receipt time of a previously received measurement from the sensor;
updating a numerator by adding a numerator value based on an inverse square of the current measurement receipt interval;
updating a denominator by adding a denominator value based on inverse fourth power of the current measurement receipt interval; and
computing an expected measurement receipt interval based on a ratio of the numerator to the denominator.

13. The method of claim 12, further comprising:
performing a remedial action at a system including the sensor if a next measurement is not received from the sensor within a time interval based on the expected measurement receipt interval.

14. The method of claim 12, wherein updating the numerator comprises adding the numerator value to a current value of the numerator weighted by a decay factor,
wherein updating the denominator comprises adding the denominator value to a current value of the denominator weighted by the decay factor,
and wherein the decay factor increases how quickly measurement receipt interval changes are reflected within the computed expected measurement receipt interval.

15. The method of claim 14, wherein the decay factor is defined as two to a power of a negative inverse of a half-life specified as a number of measurements received from the sensor.

16. The method of claim 12, wherein each of the numerator value and the denominator value is further based on a proximity effect weight taking into account how close the current measurement receipt interval is to a previously computed expected measurement receipt interval.

17. The method of claim 16, wherein the proximity effect weight is based on a base two logarithm of a square of a prior computation of the expected measurement receipt interval divided by a square of the current measurement receipt interval.

18. The method of claim 16, wherein the proximity effect weight includes a selectivity parameter to bias the proximity effect weight towards temporally later computations of the expected measurement receipt interval and away from temporally earlier computations of the expected measurement receipt interval.

19. The method of claim 12, wherein computing the expected measurement receipt interval comprises computing the expected measurement receipt interval as a square root of the ratio of the numerator to the denominator.

20. A system comprising:
communication hardware to receive a plurality of measurements from a sensor, consecutive measurements arriving over successive measurement receipt intervals;
a processor; and
a non-transitory computer-readable data storage medium to store instructions that the processor is to execute to successively update an expected measurement receipt interval when a next measurement is to be received from the sensor as a lowest mode of the measurement receipt intervals as the measurements are received from the sensor.
